(19) United States
(12) Patent Application Publication
(10) Pub. No.: US 2025/0329700 A1
(43) Pub. Date: Oct. 23, 2025

(54) SEMICONDUCTOR PACKAGING METHOD, SEMICONDUCTOR ASSEMBLY COMPONENT AND ELECTRONIC DEVICE

(71) Applicant: Yibu Semiconductor Co., Ltd., Shanghai (CN)

(72) Inventor: Ming Li, Shanghai (CN)

(73) Assignee: Yibu Semiconductor Co., Ltd., Shanghai (CN)

(21) Appl. No.: 19/187,933

(22) Filed: Apr. 23, 2025

(30) Foreign Application Priority Data
Apr. 23, 2024 (CN) 202410492912.9

(51) Int. Cl. H01L 25/18; H01L 21/48; H01L 21/56; H01L 21/683; H01L 23/00; H01L 23/528; H10B 80/00; H10D 80/30

(52) U.S. Cl. CPC H01L 25/18; H01L 21/4846; H01L 21/565; H01L 21/6835; H01L 23/528; H10B 80/00; H10D 80/30; H01L 24/16; H01L 2224/16145; H01L 2224/16225; H01L 2225/06513; H01L 2225/06517; H01L 2924/14361

(57) ABSTRACT

A semiconductor packaging method adopts a back-side power supply transmission mode, and includes a first interconnection structure and a second interconnection structure on one side of a driver layer, and a third interconnection structure on an opposite side of the driver layer. The driver layer transmits driving signals to a semiconductor device through the first interconnection structure and the second interconnection structure. The driver layer is electrically connected to the third interconnection structure, and the third interconnection structure is used for transmitting a voltage to the driver layer. As a result, the sizes of the interconnection structures are reduced, reducing costs and improving over problems such as voltage drop and delay time. Meanwhile, compared with the layer-by-layer preparation methods, the first interconnection structure and the second interconnection structure can be prepared separately and concurrently before being electrically connected, resulting in shortened packaging time and improved production efficiency.

### CROSS REFERENCE TO RELATED APPLICATION

The present application claims the benefit of priority under the Paris Convention to Chinese Patent Application No. 202410492912.9, filed on Apr. 23, 2024, which is incorporated herein by reference in its entirety.

### TECHNICAL FIELD

The disclosure relates to the field of semiconductor technology, and to a semiconductor packaging method, a semiconductor assembly component and an electronic device.

### BACKGROUND

With the development of Integrated Circuit technology, 3D and 2.5D System-In-Package (SIP) and Through-Silicon Via (TSV) technologies are becoming increasingly mature, providing a foundation for developing high bandwidth, high capacity memory products. In response to the demand for high bandwidth, high capacity and low power consumption of memory, the Joint Electron Devices Engineering Council (JEDEC) successively establishes and develops five generations of the High Bandwidth Memory (HBM) standards, i.e., HBM1, HBM2, HBM 2E, HBM 3 and HBM 3E, where the single pin rate of HBM 3E chip reaches 9.6 Gb/s, the total bandwidth of a single chip 1229 Gb/s is realized, 16 layer—stacks are supported, the maximum storage capacity of the single chip reaches 64 Gb, and the development direction is determined for a new generation of high bandwidth memory.

In the related technology, HBMs connect 3D vertically stacked Dynamic Random Access Memory (DRAM) chips with each other using Through-Silicon Vias and Micro-Bump technologies to form a three-dimensional Chip stack. The HBMs are then stacked above a System on Chip (SoC) by a face-to-face bonding method, which requires the TSVs to be opened in the SoC, and the HBMs are electrically connected to external devices through the TSV, resulting in higher process cost and lower performance of the SoC.

### SUMMARY

To solve the above technical problems, the present disclosure provides a semiconductor packaging method, a semiconductor assembly component and an electronic device.

In the first aspect, the present disclosure provides a semiconductor packaging method, comprising:

Providing a first carrier, and forming a first interconnection structure on one side of the first carrier; and

Providing a driver layer attached to a silicon substrate, and forming a second interconnection structure on one side of the driver layer away from the silicon substrate; the second interconnection structure is electrically connected to the driver layer.

Attaching the first interconnection structure to the second interconnection structure; the first interconnection structure is electrically connected to the second interconnection structure.

Removing the silicon substrate to expose one side of the driver layer away from the second interconnection structure.

Forming a third interconnection structure on one side of the driver layer away from the second interconnection structure; the third interconnection structure is electrically connected to the driver layer.

Providing a second carrier and attaching the second carrier to the third interconnection structure.

Removing the first carrier to expose the first interconnection structure.

Providing a semiconductor device and attaching to the first interconnection structure.

In some embodiments, the semiconductor packaging method further includes:

Forming a molding layer on one side of the first interconnection structure, which faces the semiconductor device; the molding layer covers the semiconductor device and the surface of the first interconnection structure, which is not occupied by the semiconductor device.

Thinning the molding layer until the surface of one side of the molding layer, which faces away from the first interconnection structure, exposes the semiconductor device.

In some embodiments, the thinning the molding layer until the semiconductor device is exposed on the side of the molding layer facing away from the first interconnection structure, and the semiconductor packaging method further comprises:

Removing the second carrier to expose one side of the third interconnection structure away from the driver layer.

Forming a first connection terminals on one side of the third interconnection structure away from the driver layer.

In some embodiments, after forming the first connection terminals on one side of the driver layer away from the third interconnection structure, the semiconductor packaging method further includes:

Providing a substrate and attaching to the first connection terminal.

In some embodiments, after attaching the substrate to the connection terminal, the semiconductor packaging method further includes:

Forming an external connection terminals on one side of the substrate away from the connection terminal.

In some embodiments, the driver layer includes transistors and a power supply circuit.

In some embodiments, the semiconductor device includes a high bandwidth storage memory chip.

In the second aspect, the present disclosure also provides a semiconductor assembly packaged made by one of the above-described semiconductor packaging methods.

In the third aspect, the present disclosure also provides an electronic device, including: the semiconductor assembly component.

Compared with the prior technology, the technical solution provided by the disclosure has the following advantages:

The embodiment of the disclosure provides a semiconductor packaging method, a semiconductor component and an electronic device, wherein the semiconductor packaging method comprises the following steps: providing a first carrier, and forming a first interconnection structure on one side of the first carrier; and providing a driver layer attached to the silicon substrate, and forming a second interconnection structure on a side of the driver layer away from the silicon substrate; the second interconnection structure is electrically connected to the driver layer; attaching the first interconnection structure to the second interconnection structure; the first interconnection structure is electrically connected to the second interconnection structure; removing the silicon substrate to expose one side of the driver layer away from the second interconnection structure; forming a third interconnection structure on one side of the driver layer away from the second interconnection structure; the third interconnection structure is electrically connected to the driver layer; providing a second carrier and attaching the second carrier to the third interconnection structure; removing the first carrier to expose the first interconnection structure; providing a semiconductor device and attaching to the first interconnection structure. Therefore, the semiconductor packaging method adopts a back-side power supply transmission (Backside Power Delivery, BSPD) mode, the first interconnection structure or the second interconnection structure and the third interconnection structure are respectively located on two sides of the driver layer, the driver layer transmits driving signals to the semiconductor device through the first interconnection structure and the second interconnection structure, the driver layer is electrically connected to the third interconnection structure, and the third interconnection structure is used for transmitting voltage to the driver layer, As a result, the size scale of the interconnection structure is reduced to a certain extent, which is beneficial to reducing costs and improving problems such as voltage drop and delay time. Meanwhile, compared with the layer-by-layer preparation method, the first interconnection structure and the second interconnection structure in the embodiment of the present disclosure are prepared simultaneously and then are electrically connected, which shortens the packaging time and is beneficial to improving production efficiency.

### BRIEF DESCRIPTION OF THE DRAWINGS

The accompanying drawings, which are incorporated in and constitute a part of this specification, illustrate embodiments consistent with the disclosure and together with the description, explain the principles of the disclosure.

In order to more clearly illustrate the embodiments of the present disclosure or the solutions in the prior technology, the drawings that are required for the description of the embodiments or the prior technology will be briefly described below, and it will be obvious to those skilled in technology that other drawings can be obtained from these drawings without inventive efforts.

FIG. 1 is a schematic structural diagram of a 3D advanced package semiconductor device provided in a related technology.

FIG. 2 is a schematic flowchart of a semiconductor packaging method according to an embodiment of the disclosure.

FIGS. 3 to 13 are schematic structural diagrams corresponding to various steps of a semiconductor packaging method according to an embodiment of the disclosure.

The following components according to some embodiments are shown in the drawings: a first carrier 11; a silicon substrate 12; a second carrier 13; a first interconnection structure 21; a second interconnection structure 22; a third interconnection structure 23; a driver layer 3; a semiconductor device 4; a molding layer 5; a first connection terminals 6; a substrate 7; and an external connection terminals 8.

### DETAILED DESCRIPTION OF THE EMBODIMENTS

In order that the above objects, features and advantages of the present disclosure may be more clearly understood, further description of aspects of the present disclosure will be provided below. It should be noted that, without conflict, the embodiments of the present disclosure and features in the embodiments may be combined with each other.

In the following description, numerous specific details are set forth to provide a thorough understanding of the present disclosure, but the present disclosure may be practiced otherwise than as described herein; it will be apparent that the embodiments in the specification are only some, but not all, embodiments of the disclosure.

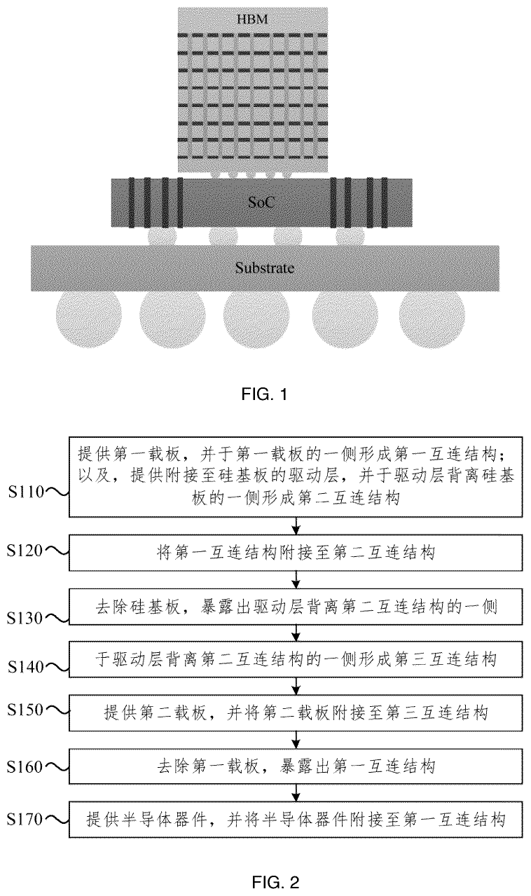

As shown in FIG. 1, an HBM according to a related technology is directly stacked above an SoC, the HBM is electrically connected to an active surface of the SoC, the SoC including TSVs, and the HBM is electrically connected to a substrate located on a passive surface of the SoC through TSV process, the substrate is used for connecting the power supply. The TSVs are formed using TSV processes, resulting in higher cost and lower performance of the SoC.

In the related technology, the electric connection between the HBM and the SoC and the electric connection between the HBM and the power supply are realized by adopting a front power supply transmission (Frontside Power Delivery, FSPD) mode, and the signal transmission between the HBM and the SoC and the voltage transmission between the HBM and the power supply all pass through a same metal layer.

In order to solve the above technical problems, embodiments of the present disclosure provide a semiconductor packaging method, a semiconductor assembly, and an electronic device, where the semiconductor packaging method includes: providing a first carrier, and forming a first interconnection structure on one side of the first carrier; and providing a driver layer attached to the silicon substrate, and forming a second interconnection structure on a side of the driver layer away from the silicon substrate; the second interconnection structure is electrically connected to the driver layer; attaching the first interconnection structure to the second interconnection structure; the first interconnection structure is electrically connected to the second interconnection structure; removing the silicon substrate to expose one side of the driver layer away from the second interconnection structure; forming a third interconnection structure on one side of the driver layer away from the second interconnection structure; the third interconnection structure is electrically connected to the driver layer; providing a second carrier and attaching the second carrier to the third interconnection structure; removing the first carrier to expose the first interconnection structure; providing a semiconductor device and attaching to the first interconnection structure. Therefore, the semiconductor packaging method adopts a back-side power supply transmission mode, the first interconnection structure or the second interconnection structure and the third interconnection structure are respectively located on two sides of the driver layer, the driver layer transmits driving signals to the semiconductor device through the first interconnection structure and the second interconnection structure, the driver layer is electrically connected to the third interconnection structure, and the third interconnection structure is used for transmitting voltages to the driver layer. As a result, the size scale of the interconnection structure is reduced to a certain extent, which is beneficial to reducing costs and lessening problems such as voltage drop and delay time. Meanwhile, compared with the layer-by-layer preparation method, the first interconnection structure and the second interconnection structure in the embodiment of the present disclosure are prepared simultaneously and then are electrically connected, which shortens the packaging time and is beneficial to improving production efficiency.

The following describes exemplary embodiments of a semiconductor packaging method, a semiconductor assembly, and an electronic device according to embodiments of the present disclosure with reference to the accompanying drawings.

In some embodiments, as shown in FIG. 2, a semiconductor packaging method is provided in an embodiment of the disclosure. Referring to FIG. 2, the semiconductor packaging method includes steps S110, S120, S130, S140, S150, S160, and S170.

S110, providing a first carrier, and forming a first interconnection structure on one side of the first carrier; and providing a driver layer attached to a silicon substrate, and forming a second interconnection structure on a side of the driver layer away from the silicon substrate.

The present step may be subdivided into two sub-steps, namely, the preparation of the first interconnection structure and the preparation of the second interconnection structure, and the sequence of these two sub-steps is not limiting in the embodiments of the present disclosure. Compared with the mode of layer-by-layer preparation, the two sub-steps can be carried out simultaneously, shortening the packaging cycle time and improving the production efficiency.

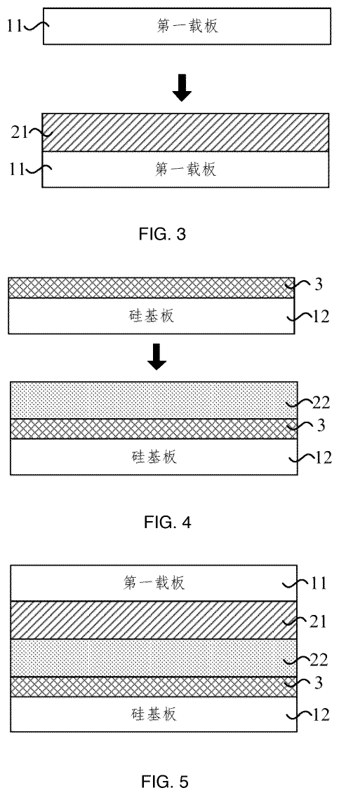

As shown in FIG. 3, a first interconnection structure 21 is formed on one side of the first carrier 11. The first interconnection structure 21 includes, but is not limited to, a redistribution layer, a set of conductive pillars, or a set of metal bumps.

As shown in FIG. 4, the driver layer 3 is formed on a surface on one side of the silicon substrate 12, and then a second interconnection structure 22 is formed on the side of the driver layer 3 facing away from the silicon substrate 12, the second interconnection structure 22 being electrically connected to the driver layer 3. The second interconnection structure 22 includes, but is not limited to, a redistribution layer, a set of conductive pillars, or a set of metal bumps.

The type of the first carrier 11 is not limiting in the embodiments of the present disclosure, and any type of carrier known to those skilled in the technology may be used, such as a wafer carrier, a silicon-based carrier, a glass carrier, or a metal carrier.

In this embodiment, the driver layer 3 includes driving devices (e.g., transistors) and a power supply circuit. The driving devices function as in the SoC in the related art for transmitting the driving signals to the semiconductor device 4 described below. The power supply circuit is electrically connected to the driving device, and the power supply circuit is also electrically connected to the third interconnection structure 23, and an external power supply may supply one or more voltages to the driving devices through the third interconnection structure 23. In some embodiments, each drive device includes one or more Thin Film Transistors (TFT) and/or one or more Complementary Metal Oxide Semiconductor (CM OC) transistors, without limitation.

S120, attaching the first interconnection structure to the second interconnection structure.

As shown in FIG. 5, a surface on one side of the first interconnection structure 21 facing away from the first carrier 11 is attached to a surface on one side of the second interconnection structure 22 facing away from the driver layer 3, and the first interconnection structure 21 is electrically connected to the second interconnection structure 22. The electrical connection of the first interconnection structure 21 and the second interconnection structure 22 may be achieved by all bonding means known to those skilled in the technology, such as Hybrid Bonding (HB), which is not limiting herein.

S130, removing the silicon substrate, and exposing one side of the driver layer away from the second interconnection structure.

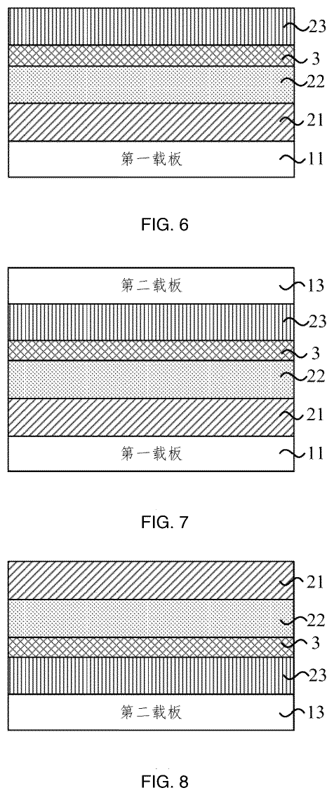

As shown in FIG. 6, the package structure obtained in step S120 is flipped over with the silicon substrate 12 on top, and the silicon substrate 12 is removed using a grinding processes known to those skilled in the technology. After removal of the silicon substrate 12, a surface on one side of the drive layer 3 facing away from the second interconnection structure 22 is exposed.

S140, forming a third interconnection structure on one side of the driver layer away from the second interconnection structure.

As shown in FIG. 6, a third interconnection structure 23 is formed on the side of the drive layer 3 facing away from the second interconnection structure 22. The third interconnection structure 23 includes, but is not limited to, a redistribution layer, a set of conductive pillars, or a set of metal bumps. The third interconnection structure 23 is electrically connected to the driver layer 3, and the third interconnection structure 23 may be electrically connected to an external power source, so that a voltage may be transmitted to the driver layer 3.

S150, providing a second carrier and attaching the second carrier to the third interconnection structure.

As shown in FIG. 7, the second carrier 13 is attached to the side of the third interconnection structure 23 facing away from the drive layer 3.

The type of the second carrier 13 is not limiting in the embodiments of the present disclosure, and any type of carrier known to those skilled in the technology may be used, such as a wafer carrier, a silicon-based carrier, a glass carrier, or a metal carrier.

S160, removing the first carrier to expose the first interconnection structure.

As shown in FIG. 8, the package structure obtained in step S150 is turned over, so that the first carrier 11 is located on the uppermost position, and after the first carrier 11 is removed, the side of the first interconnection structure 21 facing away from the second interconnection structure 22 is exposed. The first carrier 11 may be removed by at least one of laser de-bonding, thermal de-bonding, mechanical de-bonding or grinding processes.

S170, providing a semiconductor device and attaching the semiconductor device to the first interconnection structure.

In some embodiments, the semiconductor device 4 includes, among other things, High Bandwidth Memory (HBM) chips including, but not limited to, HBM 1, HBM 2, HBM 2E, HBM 3, HBM 3E, and HBM 4.

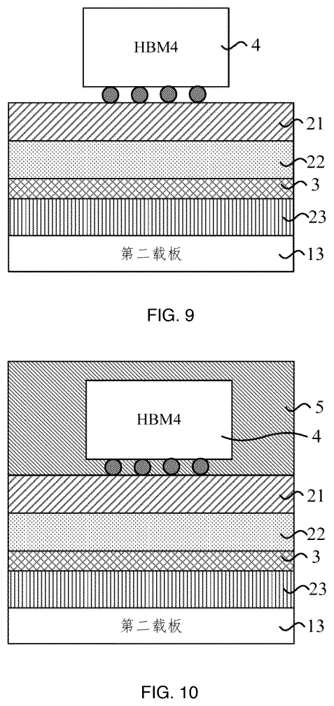

As shown in FIG. 9, the semiconductor device 4 is attached to one side of the first interconnection structure 21 facing away from the second interconnection structure 22, and the semiconductor device 4 is electrically connected to the first interconnection structure 21.

The first interconnection structure 21 and the second interconnection structure 22 are located above the driver layer 3, and the driver layer 3 is electrically connected to the semiconductor device 4 through the first interconnection structure 21 and the second interconnection structure 22, so that the driver layer 3 transmits a driving signal to the semiconductor device 4 through the second interconnection structure 22 and the first interconnection structure 21.

The third interconnection structure 23 is located under the driver layer 3, and the third interconnection structure 23 is electrically connected to the driver layer 3, the third interconnection structure 23 being used for connecting an external device, such as a substrate or a power supply, and is used to provide the supply of a voltage to the driver layer 3 and the semiconductor device 4.

In this embodiment, the first interconnection structure 21 and the second interconnection structure 22 are used for transmitting signals, the third interconnection structure 23 is used for transmitting voltages, the signal transmission structure and the voltage transmission structure are respectively located above and below the driver layer 3 by adopting the back-side power transmission mode. As a result, the size scale of the interconnection structure is reduced to a certain extent, which is beneficial to reducing costs and improving problems such as voltage drop and delay time.

According to the semiconductor packaging method provided by the embodiment of the disclosure, a back-side power supply transmission mode is adopted, the first interconnection structure 21 or the second interconnection structure 22 and the third interconnection structure 23 are respectively located on two sides of the driver layer 3, the driver layer 3 transmits driving signals to the semiconductor device 4 through the first interconnection structure 21 and the second interconnection structure 22, the driver layer 3 is electrically connected to the third interconnection structure 23, and the third interconnection structure 23 is used for transmitting voltage to the driver layer 3, As a result, the size scale of the interconnection structure is reduced to a certain extent, which is beneficial to reducing costs and improving problems such as voltage drop and delay time. Meanwhile, compared with the layer-by-layer preparation method, the first interconnection structure and the second interconnection structure in the embodiment of the present disclosure are prepared separately and concurrently, and are subsequently electrically connected, resulting in shortened the packaging time and improvement in production efficiency.

In some embodiments, after “attaching the semiconductor device to the first interconnection structure”, the semiconductor packaging method further comprises the steps of:
Forming a molding layer on one side of the first interconnection structure facing the semiconductor device; and
Thinning the molding layer until the semiconductor device is exposed on one side of the molding layer facing away from the first interconnection structure.

As shown in FIG. 10, the molding layer 5 encapsulates the semiconductor device 4 and also covers portions of the first interconnection structure 21 not occupied by the semiconductor device 4. The molding layer 5 may be a prepreg, which is used to cover the semiconductor device 4, and the prepreg includes one or more of epoxy resin, polyethylene, polypropylene, polyolefin, polyamide, polyurethane, and the like. The molding layer 5 may be made of a liquid or powder epoxy resin, and may not only covers the semiconductor device 4, but also fills in the gaps between the semiconductor device 4 and the first interconnection structure 21. The molding layer 5 not only reinforces the connection of the semiconductor device 4 with the first interconnection structure 21, but also protects the semiconductor device from corrosion and damage in an external environment.

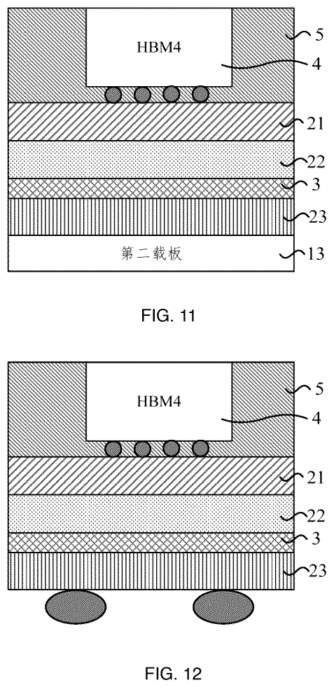

As shown in FIG. 11, the molding layer 5 is thinned by a grinding or etching process until the semiconductor device 4 is exposed on the side of the molding layer 5 facing away from the first interconnection structure 21.

In some embodiments, after “thinning the molding layer until the semiconductor device is exposed on one side of the molding layer facing away from the first interconnection structure”, the semiconductor packaging method further includes the steps of:

Removing the second carrier to expose one side of the third interconnection structure away from the driver layer.

Forming first connection terminals on a side of the third interconnection structure away from the driver layer.

As shown in FIG. 12, at least one of laser de-bonding, thermal de-bonding, mechanical de-bonding or grinding may be used to remove the second carrier 13, expose a surface of a side of the third interconnection structure 23 facing away from the driver layer 3, and then the first connection terminals 6 are formed on a side of the third interconnection structure 23 facing away from the driver layer. The first connection terminals 6 include at least one of a pad, a bump, and a solder ball. The first connection terminals 6 are for connecting a substrate.

In some embodiments, after the first connection terminals 6 are formed, the semiconductor packaging method further includes the steps of:

Providing a substrate and attaching the substrate to the first connection terminal.

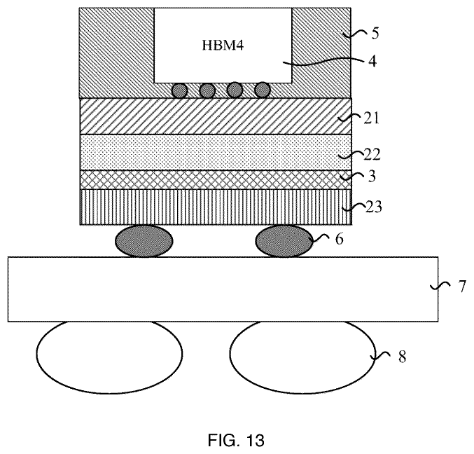

As shown in FIG. 13, the substrate 7 includes an Ajinomoto Build-up Film (ABF) substrate and a bismaleimide/triazo well resin (Bismaleimide Triazine, BT) substrate.

In some embodiments, after “attach a substrate to the connection terminal”, the semiconductor packaging method further includes the steps of:

Forming external connection terminals on one side of the substrate away from the first connection terminal.

As shown in FIG. 13, the external connection terminals 8 are formed on the side of the substrate 7 facing away from the first connection terminals 6. The substrate 7 is provided with a through hole penetrating through the thickness thereof, and the through hole is filled with a conductive material so as to electrically connect the first connecting terminals 6 located above the substrate 7 with the external connection terminals 8 located below the substrate 7. The external connection terminals 8 are used for connecting an external device such as a Printed Circuit Board (PCB) or a power supply. The external connection terminals 8 include at least one of a pad, a bump, and a solder ball.

On the basis of the foregoing embodiments, the embodiments of the present disclosure further provide a semiconductor assembly component, where the semiconductor assembly component is packaged by any one of the foregoing semiconductor packaging methods, and has corresponding beneficial effects, and to avoid repetitive description, no further description is given here.

On the basis of the foregoing implementation embodiments, the embodiment of the present disclosure further provides an electronic device, which includes the semiconductor component and has corresponding beneficial effects, and to avoid repeated description, the description is omitted herein.

It should be noted that in this document, relational terms such as “first” and “second” and the like are used solely to distinguish one entity or action from another entity or action without necessarily requiring or implying any actual such relationship or order between such entities or actions. Moreover, the terms “comprises,” “comprising,” or any other variation thereof, are intended to cover a non-exclusive inclusion, such that a process, method, material, or equipment that comprises a list of elements does not include only those elements but may include other elements not expressly listed or inherent to such process, method, material, or equipment. Without further limitation, an element defined by the phrase “comprising one . . . ” does not exclude the presence of other like elements in a process, method, material, or equipment that comprises the element.

The foregoing is merely a specific embodiment of the disclosure to enable one skilled in the technology to understand or practice the disclosure. Various modifications to these embodiments will be readily obvious to those skilled in the technology, and the generic principles defined herein may be applied to other embodiments without departing from the spirit or scope of the disclosure. Thus, the present disclosure is not intended to be limited to the embodiments shown and described herein but is to be accorded the widest scope consistent with the principles and novel features disclosed herein.

What is claimed is:

1. A semiconductor packaging method, comprising:
forming a first interconnection structure on a first carrier; and
providing a silicon substrate having a driver layer attached to thereto, and forming a second interconnection structure on a first side of the driver layer away from the silicon substrate, wherein the second interconnection structure is electrically connected to the driver layer;
attaching the first interconnection structure to the second interconnection structure, wherein the first interconnection structure is electrically connected to the second interconnection structure;
removing the silicon substrate to expose a second side of the driver layer away from the second interconnection structure;
forming a third interconnection structure on the second side of the driver layer, wherein the third interconnection structure is electrically connected to the driver layer;
attaching a second carrier to the third interconnection structure;
removing the first carrier to expose the first interconnection structure; and
attaching a semiconductor device to the first interconnection structure.

2. The semiconductor packaging method of claim 1, further comprising:
forming a molding layer on one side of the first interconnection structure facing the semiconductor device, wherein the molding layer covers the semiconductor device and portions of the surface of the first interconnection structure not occupied by the semiconductor device;
thinning the molding layer until the semiconductor device is exposed on the side of the molding layer facing away from the first interconnection structure.

3. The semiconductor packaging method of claim 2, wherein the thinning the molding layer until after the semiconductor device is exposed on the side of the molding layer facing away from the first interconnection structure, the semiconductor packaging method further comprises:
removing the second carrier to expose one side of the third interconnection structure away from the driver layer;
forming first connection terminals on one side of the third interconnection structure away from the driver layer.

4. The semiconductor packaging method of claim 3, wherein, after forming a first connection terminals on one side of the driver layer away from the third interconnection structure, the semiconductor packaging method further comprises:
attaching a substrate to the first connection terminal.

5. The semiconductor packaging method of claim 4, wherein, after attaching the substrate to the connection terminal, the semiconductor packaging method further comprises:
forming external connection terminals on one side of the substrate away from the connection terminal.

6. The semiconductor packaging method of claim 1, wherein the driver layer comprises transistors and a power supply circuit.

7. The semiconductor packaging method of claim 1, wherein the semiconductor device comprises a high bandwidth memory device.

8. A semiconductor assembly component packaged using the semiconductor packaging method according to claim ′.

9. An electronic device, comprising: the semiconductor assembly component of claim 8.
